(19) United States
(12) Patent Application Publication
(10) Pub. No.: US 2025/0208518 A1
(43) Pub. Date: Jun. 26, 2025

(54) ELECTRON PROBE POSITIONING PATTERN, DISPLACEMENT MEASUREMENT METHOD, AND POSITIONING CONTROL METHOD

(71) Applicant: HUNAN UNIVERSITY, Changsha (CN)

(72) Inventor: Koichi MATSUDA, Changsha (CN)

(73) Assignee: HUNAN UNIVERSITY, Changsha, HN (CN)

(21) Appl. No.: 18/780,548

(22) Filed: Jul. 23, 2024

(30) Foreign Application Priority Data
Dec. 25, 2023 (CN) 2023117904125

(51) Int. Cl. G03F 7/00

(52) U.S. Cl. CPC G03F 7/70516; G03F 7/70008; G03F 7/7005; G03F 7/704; G03F 7/70508; G03F 7/70525

(57) ABSTRACT

The present invention discloses an electron probe positioning pattern, displacement measurement method, and positioning control method. A marker region on the substrate comprises a first line set with multiple continuous first lines and a second line set with multiple discontinuous second lines. The first and second line sets are orthogonal, with the spacing of the first line set on the scanning line differing from the spacing of the second line set. This configuration allows the periodic signals of the spacing of both line sets to be separated from a secondary electron-based video signal obtained by scanning the pattern. This separation facilitates the calculation of the electron probe's displacement in two dimensions, enabling the elimination of displacement in subsequent real-time control.

### TECHNICAL FIELD

The present invention relates to the technical field of lithography equipment, in particular to an electron probe positioning pattern, displacement measurement method, and positioning control method.

### BACKGROUND ART

The electron beam lithography equipment comprises a beam device, a wafer stage, a substrate, and a control system, the substrate is arranged on the wafer stage. The existing beam devices generally comprise an electron gun, a beam blanker, a condenser lens, an aperture, a scanning coil, a controller, etc, the electron beam lithography equipment has high requirements for the positioning accuracy of the electron probe generated by the beam device, however, the structural vibration caused by the floor vibration and the wafer stage movement will cause the vibration of the electron probe and deteriorate the positioning accuracy of the electron probe.

In order to solve this problem, many methods have been proposed, such as wafer stage positioning control and external vibration isolation technology. The vibration isolation technology comprises providing a rubber pad, a coil spring, a damper, or a shock absorber to achieve vibration damping; for positioning control, the electron probe displacement is finally measured by a microscopic image of the circuit pattern obtained by lithography test, this microscopic image can be directly used for vibration control. At present, the special marker structure image used for the measurement of the displacement of the electron probe is a uniform linear pattern along one direction, which is only suitable for the probe displacement in one direction, as shown in FIG. 1, wherein, FIG. 1a is a conventional marker structure image, FIG. 1b is a microscopic image of the electron probe scanning marker pattern without vibration, and FIG. 1c is a microscopic image of the electron probe scanning marker pattern with vibration, and measuring the displacement of the probe in the two-dimensional plane also requires reconfiguring the marker structure pattern (the marker needs to rotate pattern by 90 degrees to measure a probe displacement in the direction orthogonal to the original marker pattern). It is necessary to fit the simulated microscopic image with the measured microscopic image when calculating the displacement of the electron probe by the microscopic image of the vibration, the calculation load is high, which is far from meeting the real-time control application.

### SUMMARY

The present invention provides an electron probe positioning pattern, displacement measurement method, and positioning control method to solve the problem that the existing substrate marker image is only applicable to a displacement measurement of an electronic beam in one direction, and the calculation load is high, which is far from meeting the real-time control application.

In a first aspect, an electron probe positioning pattern is provided, a marker region of the electron probe positioning pattern comprises a first line set composed of multiple continuous first lines and a second line set composed of multiple discontinuous second lines, the first line set and the second line set are orthogonal, and a spacing of the first line set on a scanning line is not equal to a spacing of the second line set on the scanning line.

By setting multiple orthogonal first lines and second lines, and the spacing of the first line set on a scanning line is not equal to the spacing of the second line set on the scanning line, periodic signals of the spacing of the first line set and the spacing of second line set on the scanning line can be separated from a secondary electron-based video signal obtained by scanning the pattern, so as to facilitate a calculation of the displacement of the electron probe in two directions in the two-dimensional plane.

According to the first aspect, in a possible realization method, the spacing of the first line set on the scanning line and the spacing of the second line set on the scanning line satisfy the following conditions:

$${P}^{″} = P / sin R , {Q}^{″} = Q / cos R$$

$${P}^{″} = α {Q}^{″}$$

$$α > 3 / 2 or α < 2 / 3$$

where P″ denotes the spacing of the first line set on the scanning line; Q″ denotes the spacing of the second line set on the scanning line; P denotes the spacing of the first line set, Q denotes the spacing of the second line set; R denotes an angle between the scanning line and the first line set.

According to the first aspect, in a possible realization method, the projection lengths of the following three on the scanning line are greater than the horizontal pixel resolution; a line width of the first line, a line width of the second line, and a spacing between the adjacent first and second lines.

In a second aspect, an electronic probe displacement measurement method is provided, comprising:
obtaining an electron probe scanning video signal W′(t) of the electron probe positioning pattern as described in any of the first aspects in real-time;
the Fourier decomposition of the video signal W′(t) is performed to obtain its fundamental waves F₁′^{(t)} and G₁′^{(t)}, as well as the phases γ₁′ and ϕ₁′ of F₁′^{(t)} and G₁′^{(t)}; F₁′(t) and G₁′^{(t)} denote a fundamental signal of the spacing of the first line set on the scanning line and the fundamental signal of the spacing of second line set on the scanning line obtained in real-time, respectively;
a displacement (u,v) of the current scanning round of the electron probe is expressed as follows:

$$u = P ( {γ}_{1}^{′} - {γ}_{1} ) / ( 2 π ) , v = Q ( {ϕ}_{1}^{′} - {ϕ}_{1} ) / ( 2 π )$$

where γ₁ and ϕ₁ denote a phase of the fundamental signal of the spacing of the first line set on the scanning line and a phase of the fundamental signal of the spacing of the second line set on the scanning line when the electron probe is not vibrating respectively, P denotes the spacing of the first line set, and Q denotes the spacing of the second line set.

According to a second aspect, in a possible realization method, the video signal W′(t) is decomposed into its fundamental waves F₁′^{(t)} and G₁′^{(t)}, which are denoted as follows:

$${W}^{′ ( t )} = {F}_{1}^{′ ( t )} + {G}_{1}^{′ ( t )}$$

$${F}_{1}^{′} ( t ) = {α}_{1}^{′} sin ( {ω}_{u} t + {γ}_{1}^{′} ) , {G}_{1}^{′} ( t ) = {β}_{1}^{′} sin ( {ω}_{v} t + {ϕ}_{1}^{′} )$$

$$where , {α}_{1}^{′} = \sqrt{{( {A}_{1}^{′} )}^{2} + {( {B}_{1}^{′} )}^{2}} , {β}_{1}^{′} = \sqrt{{( {C}_{1}^{′} )}^{2} + {( {D}_{1}^{′} )}^{2}} ,$$

$${γ}_{1}^{′} = {tan}^{- 1} ( {A}_{1}^{′} / {B}_{1}^{′} ) , {ϕ}_{1} = {tan}^{- 1} ( {C}_{1}^{′} / {D}_{1}^{′} ) ;$$

$${A}_{1}^{′} = \frac{2}{{T}_{s}} {\int }_{0}^{{T}_{s}} {W}^{′} ( t ) cos {ω}_{u} t dt , {B}_{1}^{′} = \frac{2}{{T}_{s}} {\int }_{0}^{{T}_{s}} {W}^{′} ( t ) sin {ω}_{u} tdt ,$$

$${C}_{1}^{′} = \frac{2}{{T}_{s}} {\int }_{0}^{{T}_{s}} {W}^{′} ( t ) cos {ω}_{v} tdt , {D}_{1}^{′} = \frac{2}{{T}_{s}} {\int }_{0}^{{T}_{s}} {W}^{′} ( t ) sin {ω}_{v} tdt ;$$

F₁′(t) denotes the fundamental signal of the spacing of the first line set on the scanning line obtained in real-time, and G₁′^{(t)} denotes the fundamental signal of the spacing of the second line set on the scanning line obtained in real-time; Tₛ denotes a period of each scan, t denotes a time; ωᵤ=2π/Tᵤ, ωᵥ=2π/Tᵥ, Tᵤ=P″/V, Tᵥ=Q″/V, V denotes a scanning speed of the electron probe, P″ and Q″ denote the spacing of the first line set on the scanning line and the spacing of the second line set on the scanning line, respectively.

In a third aspect, the electronic probe displacement measurement method is provided, comprising:
obtaining a fundamental amplitude of θ_{N}=[A₁′(t_{N}) B₁′(t_{N}) C₁′(t_{N}) D₁′(t_{N})]^{T} at the previous time t_{N} of the current time; where the fundamental amplitude θ_{N}=[A₁′(t_{N}) B₁′(t_{N}) C₁′(t_{N}) D₁′(t_{N})]^{T} is obtained based on the t={t₁ t₂ . . . t_{N}} electron probe scanning a video signal time-series {W₁′ W₂′ . . . W_{N}′} of the electron probe positioning pattern as described in the first aspect, and W_{N}′ denotes a video signal value at time t_{N};
obtaining the video signal value of t_{N+1} at the current time, and the fundamental amplitude θ_{N+1}=[A₁′(t_{N+1}) B₁′(t_{N+1}) C₁′(t_{N+1}) D₁′(t_{N+1})]^{T} at the current time t_{N+1} is determined by a least square method;
a displacement (u(t_{N+1}), V(t_{N+1})) of the probe at a current time t_{N+1} can be expressed as follows:

$$u ( {t}_{N + 1} ) = P ( {γ}_{1}^{′} , ( {t}_{N + 1} ) - {γ}_{1} ) / ( 2 π ) , v ( {t}_{N + 1} ) = Q ( {ϕ}_{1}^{′} , ( {t}_{N + 1} ) - {ϕ}_{1} ) / ( 2 π )$$

where, γ₁′(t_{N+1})=tan⁻¹[A₁′(t_{N+1})/B₁′(t_{N+1})], ϕ₁′(t_{N+1})=tan⁻¹[C′(t_{N+1})/D₁′(t_{N+1})], γ₁ and ϕ₁ denote the phase of the fundamental signal of the spacing of the first line set on the scanning line and the phase of the fundamental signal of the spacing of the second line set on the scanning line when the electron probe is not vibrating respectively, P denotes the spacing of the first line set, and Q denotes the spacing of the second line set.

According to the third aspect, in a possible realization method, the video signal time-series {W₁′ W₂′ . . . W_{N}′} is expressed as follows:

$$[ \begin{matrix}{W}_{1}^{′} \\ {W}_{2}^{′} \\ ⋮ \\ {W}_{N}^{′}\end{matrix} ] = [ \begin{matrix}cos {ω}_{u} {t}_{1} & sin {ω}_{u} {t}_{1} & cos {ω}_{v} {t}_{1} & sin {ω}_{v} {t}_{1} \\ cos {ω}_{u} {t}_{2} & sin {ω}_{u} {t}_{2} & cos {ω}_{v} {t}_{2} & sin {ω}_{v} {t}_{2} \\ ⋮ & ⋮ & ⋮ & ⋮ \\ cos {ω}_{u} {t}_{N} & sin {ω}_{u} {t}_{N} & cos {ω}_{v} {t}_{N} & sin {ω}_{v} {t}_{N}\end{matrix} ] [ \begin{matrix}{A}_{1}^{′} \\ {B}_{1}^{′} \\ {C}_{1}^{′} \\ {D}_{1}^{′}\end{matrix} ] + [ \begin{matrix}{η}_{1} \\ {η}_{2} \\ ⋮ \\ {η}_{N}\end{matrix} ]$$

where η_{N} denotes an error at time t_{N}; ωᵤ=2π/Tᵤ, ωᵥ=2π/Tᵥ, Tᵤ=P″/V, Tᵥ=Q/V, V denotes the scanning speed of the electron probe, P″ and Q″ denote the spacing of the first line set on the scanning line and the spacing of the second line on the scanning line, respectively; the fundamental amplitude θ_{N}=[A₁′(t_{N}) B₁′(t_{N}) C₁′(t_{N}) D₁′(t_{N})]^{T} is expressed as follows:

$${θ}_{N} = {P}_{N} {\sum }_{j = 1}^{N} {z}_{j} {W}_{j}^{′}$$

where, zⱼ^{T}=[cos ωᵤtⱼ sin ωⱼtⱼ cos ωᵥtⱼ sin ωᵥtⱼ], P_{N}=(Σⱼ₌₁^{N}zⱼzⱼ^{T})⁻¹;
the least square method is used to determine the amplitude θ_{N+1} and P_{N+1} of the fundamental wave at the current time t_{N+1} is expressed as follows:

$${θ}_{N + 1} = {[ {A}_{1}^{′} ( {t}_{N + 1} ) {B}_{1}^{′} ( {t}_{N + 1} ) {C}_{1}^{′} ( {t}_{N + 1} ) {D}_{1}^{′} ( {t}_{N + 1} ) ]}^{T} = {θ}_{N} + \frac{{P}_{N} {z}_{N + 1}}{1 + {z}_{N + 1}^{T} {P}_{N} {z}_{N + 1}} ( {W}_{N + 1}^{′} - {z}_{N + 1}^{T} {θ}_{N} )$$

$${P}_{N + 1} = {P}_{N} - \frac{{P}_{N} {z}_{N + 1} {z}_{N + 1}^{T} {P}_{N}}{1 + {z}_{N + 1}^{T} {P}_{N} {z}_{N + 1}}$$

where W_{N+1}′ denotes a video signal value at the current time t_{N+1}.

In a fourth aspect, an electronic probe positioning control method is provided, comprising:
obtaining measurement values of multiple accelerometers arranged on a vacuum chamber, an optical column and a wafer stage in real-time, and inputting them into a feed-forward controller to obtain a first input voltage of a scanning coil;
obtaining a real-time displacement of an electronic probe using the electronic probe displacement measurement method as described in any one of the second aspect or the third aspect, and inputting them into a feedback controller to obtain a second input voltage of a scanning coil;
controlling the scanning coil voltage in real-time according to a final input voltage obtained by integrating the first input voltage and a second input voltage of the scanning coil.

According to the fourth aspect, in a possible realization method, the feed-forward controller is expressed as follows:

$$[ \begin{matrix}{V}_{x} \\ {V}_{y}\end{matrix} ] = {C}^{- 1} G [ \begin{matrix}{δ}_{1} \\ {δ}_{2} \\ ⋮ \\ {δ}_{J}\end{matrix} ]$$

where, (Vₓ, V_{y}) denotes a first input voltage of the scanning coil, δ_{J} denotes a measured value of the Jth accelerometer, G denotes a transfer function from the measured values of multiple accelerometers to the displacement of the electron probe, and C denotes a transfer matrix from the displacement of the electron probe to the first input voltage of the scanning coil;
the feedback controller is expressed as follows:

$$[ \begin{matrix}{V}_{x} ( {t}_{j} ) \\ {V}_{y} ( {t}_{j} )\end{matrix} ] = {C}^{- 1} \{ [ \begin{matrix}{k}_{pu} & 0 \\ 0 & {k}_{pv}\end{matrix} ] [ \begin{matrix}u ( {t}_{j} ) \\ v ( {t}_{j} )\end{matrix} ] + [ \begin{matrix}{k}_{du} & 0 \\ 0 & {k}_{dv}\end{matrix} ] [ \begin{matrix}\dot{u} ( {t}_{j} ) \\ \dot{v} ( {t}_{j} )\end{matrix} ] \}$$

where, (Vₓ(tⱼ), V_{y}(tⱼ)) denotes the second input voltage of the scanning coil at time tⱼ, (u(tⱼ), v(tⱼ)) denotes a probe displacement at time tⱼ, kₚᵤ, kₚᵥ, k_{du}, k_{dv} are gain coefficients.

In a fifth aspect, an electron beam lithography equipment is provided, and the substrate adopts an electron probe positioning pattern as described in any of the first aspects, which comprises a marker region and an exposure region;

a beam device adopts a multi-beam device, in which one electron probe is used to scan the marker region and the other electron probes are used to scan the exposure region.

The present invention proposes an electronic probe positioning pattern, displacement measurement method, and positioning control method, which has the following beneficial effects:
(1) a new marker structure pattern is proposed, by setting multiple orthogonal first lines and second lines, and the spacing of the first line set on the scanning line is not equal to the spacing of the second line set on the scanning line, so the periodic signals of the spacing of the first line set and the spacing of second line set on the scanning line can be separated from a secondary electron-based video signal obtained by scanning the pattern, which facilitate a calculation of the displacement of the electron probe in two directions in the two-dimensional plane.
(2) based on the new marker structure pattern, according to the video signal obtained by scanning, the displacement of the electron probe in two directions can be obtained by fast calculation through Fourier decomposition or recursive least square method, and the calculation speed is fast and real-time control can be achieved;
(3) a feed-forward controller and a feedback controller are provided, wherein the feed-forward controller controls the input voltage of the scanning coil based on the measurement data of the accelerometer, and the feedback controller controls the input voltage of the scanning coil based on the calculated real-time displacement of the electronic probe, and the real-time suppression of the displacement of the electronic probe is realized through the synergistic effect of the feed-forward controller and the feedback controller.

### BRIEF DESCRIPTION OF DRAWINGS

To explain the embodiments of the present disclosure or the technical solutions in the prior art clearer, a brief introduction will be made to the accompanying drawings used in the embodiments or the description of the prior art. It is obvious that the drawings in the description below are only some embodiments of the present disclosure, and those ordinarily skilled in the art can obtain other drawings according to these drawings without creative work.

FIG. 1 is a microscopic image of the conventional marker structure pattern provided by the present invention, wherein FIG. 1a is a conventional marker structure pattern, FIG. 1b is a microscopic image of the conventional marker structure pattern without vibration, and FIG. 1c is a microscopic image of the conventional marker structure pattern with vibration;

FIG. 2 is a schematic diagram and a microscopic image of the marker region structure of the electron probe positioning pattern provided by the embodiment of the present invention; wherein FIG. 2a is a structure diagram of the marker region of the electron probe positioning pattern, FIG. 2b is a microscopic image of the marker region of the electron probe positioning pattern without vibration, FIG. 2c is a microscopic image of the marker region of the electron probe positioning pattern with vibration;

FIG. 3 is a schematic diagram of the scanning process of the marker region of the electron probe positioning pattern provided the embodiment of the present invention;

FIG. 4 is a video signal of the electron probe without vibration and a response of each fundamental wave provided by the embodiment of the present invention;

FIG. 5 is a video signal of the electron probe with vibration and response of each fundamental wave provided by the embodiment of the present invention;

FIG. 6 is a mechanical dynamics analysis diagram of the electron beam lithography equipment provided by the embodiment of the present invention;

FIG. 7 is a multi-beam device provided by the embodiment of the present invention, wherein FIG. 7a is a multi-beam device with a single electron source, and FIG. 7b is a multi-beam device with multiple electron sources.

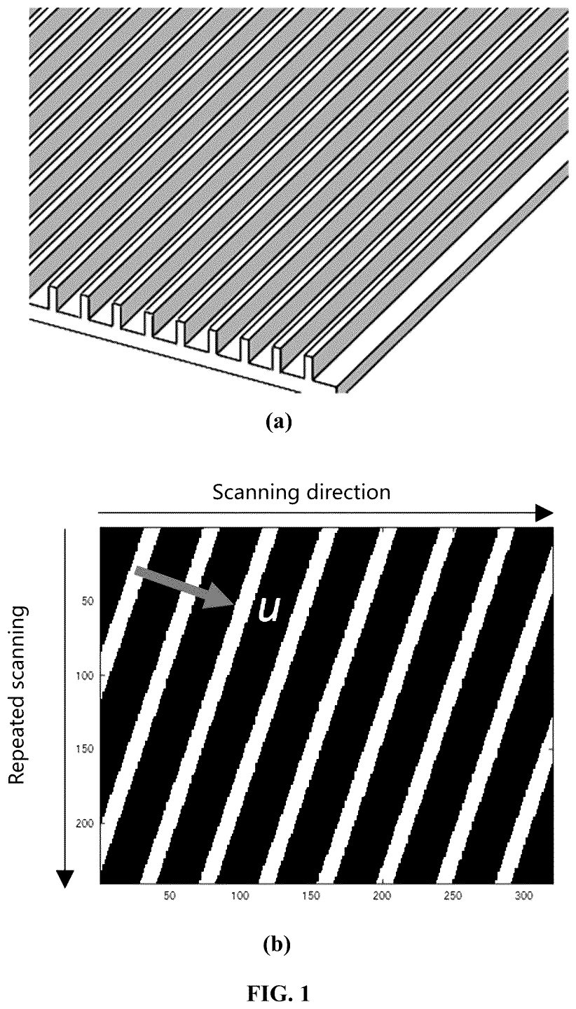

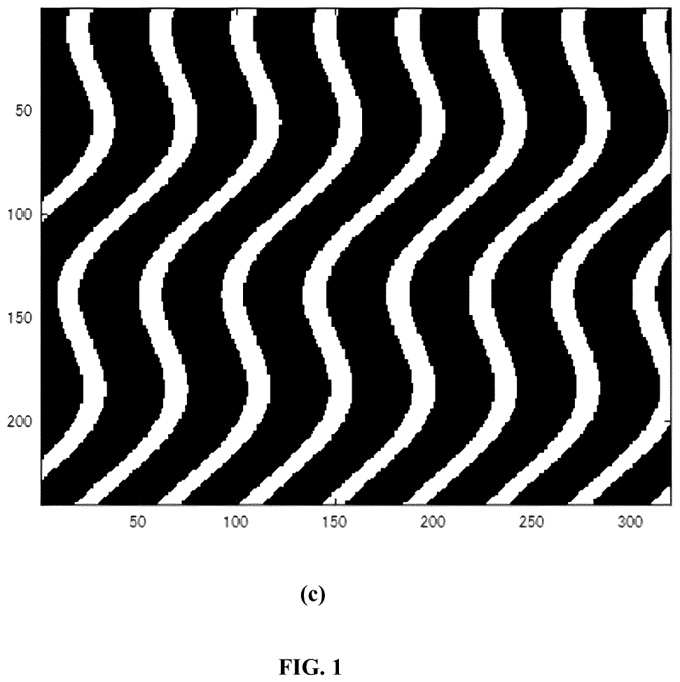

### DETAILED DESCRIPTION OF THE EMBODIMENTS

In order to make the purpose, technical scheme, and advantages of the present invention clearer, the technical scheme of the present invention is described in detail below. Obviously, the described embodiments are only part of the embodiments of the present invention, not all of the embodiments. Based on the embodiment of the present invention, all other embodiments obtained by ordinary technical personnel in the field without making creative labor are within the scope protected by the present invention.

In the above description of the present invention, it is to be noted that the orientation or positional relationship indicated by the terms “up”, “down”, “longitudinal”, “transversely”, “vertical”, “horizontal”, etc. is based on the orientation or positional relationship shown in the accompanying drawings, merely for ease of description and simplification of the description of the present invention, and not to indicate or imply that the referenced device or element must have a particular orientation and be constructed and operative in a particular orientation, and thus may not be construed as a limitation on the present invention. The terms “first”, “second”, etc. are used only for descriptive purposes and cannot be understood as indicative or suggestive of relative importance or order. In addition, in the description of the present invention, unless otherwise stated, “multiple” means at least two.

### Embodiment 1

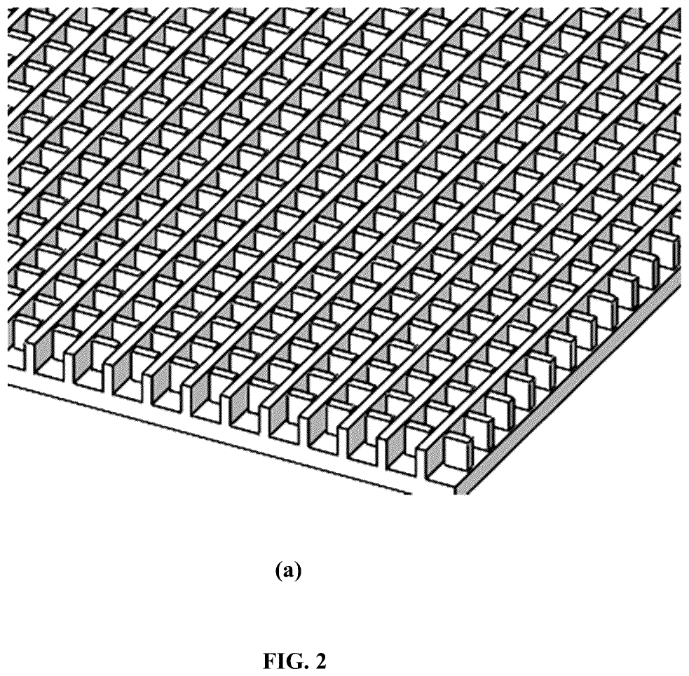

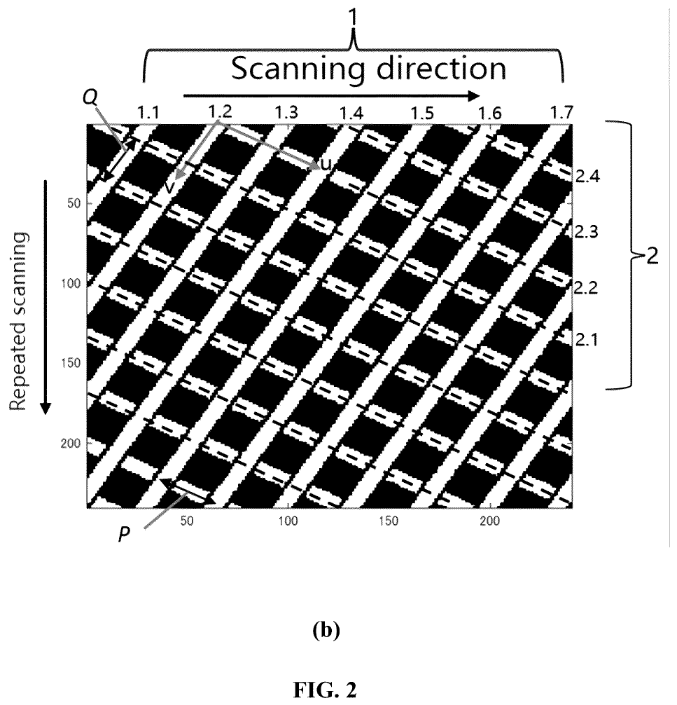

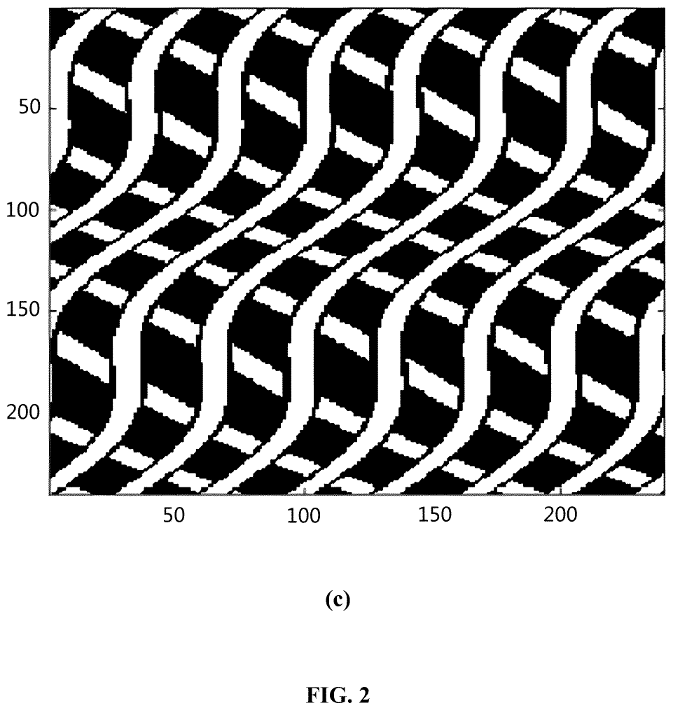

as shown in FIG. 2 and FIG. 3, the present invention provides an electron probe positioning pattern, a marker region of the electron probe positioning pattern comprises a first line set composed of multiple continuous first lines and a second line set composed of multiple discontinuous second lines, the first line set and the second line set are orthogonal, and the spacing of the first line set on the scanning line is not equal to the spacing of the second line set on the scanning line.

Specifically, the microscopic image can be obtained by scanning the marker region of the electron probe positioning pattern through the electron beam for many times. Suppose that the spacing among the first line set 1 is P, the spacing among the second line set 2 is Q, and the angle between each scanning line and the first line set 1 is R(R≠0, π/2, π, 2π), then the spacing P″ of the first line set 1 on the scanning line and the spacing Q″ of the second line set 2 on the scanning line are as follows:

$${P}^{″} = P / sin R , {Q}^{″} = Q / cos R$$

since the scanning speed of each line is constant, the measured secondary electron-based video signal contains signals with periods P″ and Q.

Therefore, in order to obtain P=αQ″ (α≠1), each spacing (P and Q) and direction R of the pattern can be appropriately selected, and the video signal generated by the first line set 1 and the second line set 2 can be separated into Wᵤ and Wᵥ by periodicity. In practical applications, when α>3/2 or α<2/3, the reliability of video signal separation will be improved. The projection lengths of the following three, the line width A of the first lines, the line width B of the second lines, and the spacing S between the adjacent first line and the second line, on the scanning line only need to be greater than the horizontal pixel resolution (W/M). W is the horizontal length of the measured microscopic image, and M is the number of pixels in the horizontal direction.

In addition, the lower detection limit of the vibration amplitude of the electron probe is determined by the horizontal pixel resolution, and the upper limit is less than W due to observability, therefore, the geometric parameters and observation magnification of the pattern should be selected according to the actual vibration amplitude.

By setting multiple orthogonal first lines and second lines, and the spacing of the first line set 1 on the scanning line is not equal to the spacing of the second line set 2 on the scanning line, the periodic signal of the spacing of the first line set on the scanning line and the spacing of the second line set on the scanning line can be separated from the secondary electron-based video signal obtained by scanning, so as to facilitate the calculation of the displacement of the electron probe in two directions in the two-dimensional plane.

### Embodiment 2

Based on the electron probe positioning pattern provided by the above-mentioned embodiment 1, the embodiment provides an electronic probe displacement measurement method, comprising:
S1: obtained in real-time of electron probe scanning video signal W′(t) of the electron probe positioning pattern as described in embodiment 1;
S2: the Fourier decomposition of the video signal W′(t) is performed to obtain its fundamental waves F₁′^{(t)} and G₁′^{(t)}, as well as the phases γ₁′ and ϕ₁′ of F₁′^{(t)} and G₁′^{(t)}; F₁′(t) and G₁′^{(t)} denote the fundamental signal of the spacing of the first line set on the scanning line and the fundamental signal of the spacing of second line set on the scanning line obtained in real-time, respectively;
S3: the displacement (u,v) of the current scanning round of the electron probe is expressed as follows:

$$u = P ( {γ}_{1}^{′} - {γ}_{1} ) / ( 2 π ) , v = Q ( {ϕ}_{1}^{′} - {ϕ}_{1} ) / ( 2 π )$$

where γ₁ and ϕ₁ denote a phase of the fundamental signal of the spacing of the first line set on the scanning line and a phase of the fundamental signal of the spacing of the second line set on the scanning line when the electron probe is not vibrating respectively, P denotes the spacing of the first line set, and Q denotes the spacing of the second line set.

Specifically, when scanning the pattern of the marker region on the substrate with an electron probe, the secondary electrons generated at this time are measured, that is, the video signal W(t). The displacement of the electron probe needs to be calculated based on the measured data during each scan of Tₛ. As previously mentioned, the video signal measured during the pattern observation of the marker region on the substrate scanned by an electron probe is a periodic signal of P″ and Q″, expressed in Fourier scales as follows:

$$W ( t ) = {\sum }_{m = 1}^{∞} ( {A}_{m} cos m {ω}_{u} t + {B}_{m} sin m {ω}_{u} t ) + {\sum }_{n = 1}^{∞} ( {C}_{n} cos n {ω}_{v} t + {D}_{n} sin n {ω}_{v} t ) + η ( t ) = {\sum }_{m = 1}^{∞} {α}_{m} sin ( m {ω}_{u} t + {γ}_{m} ) + {\sum }_{n = 1}^{∞} {β}_{n} sin ( n {ω}_{v} t + {ϕ}_{n} ) + η ( t ) = F ( t ) + G ( t ) + η ( t )$$

$$F ( t ) = {\sum }_{m} {α}_{m} sin ( m {ω}_{u} t + {γ}_{m} ) , G ( t ) = {\sum }_{n} {β}_{n} sin ( n {ω}_{v} t + {ϕ}_{n} )$$

where, αₘ=\sqrt{Aₘ²+Bₘ²}, βₙ=\sqrt{Aₙ²+Bₙ²}, βₘ=tan⁻¹(Aₘ/Bₘ) and φₙ=tan⁻¹(Cₙ/Dₙ); in addition, assumed that the scanning speed of the electron probe is V, so ωᵤ=2π/Tᵤ and ωᵥ=2π/TᵥTₙ=P″/V, Tᵥ=Q″/V; the number of sine waves of P″ and Q″ periodic signals is m and n, and the angular frequencies are integer times of ωᵤ or ωᵥ, respectively. Set F(t) and G(t) denote the periodic signals of P″ and Q″, respectively; assumed that the disturbance noise η(t) is small enough due to filtering processing and other reasons, the Fourier coefficients (Aₘ, Bₘ, Cₙ, Dₙ) are determined as follows:

$${A}_{m} = \frac{2}{{T}_{s}} {\int }_{0}^{{T}_{s}} W ( t ) cos m {ω}_{u} t d t , {B}_{m} = \frac{2}{{T}_{s}} {\int }_{0}^{{T}_{s}} W ( t ) sin m {ω}_{u} tdt$$

$${C}_{n} = \frac{2}{{T}_{s}} {\int }_{0}^{{T}_{s}} W ( t ) cos n {ω}_{v} t d t , {D}_{n} = \frac{2}{{T}_{s}} {\int }_{0}^{{T}_{s}} W ( t ) sin n {ω}_{v} t d t$$

when implemented, only the fundamental wave of the video signal is required, therefore, for simplicity, it is assumed that the video signal only contains the fundamental wave, that is, only m=1 and n=1, at this time, the video signal W(t) can be simplified as follows:

$$W ( t ) = {F}_{1} ( t ) + {G}_{1} ( t )$$

$${F}_{1} ( t ) = {α}_{1} sin ( {ω}_{u} t + {γ}_{1} ) , {G}_{1} ( t ) = {β}_{1} sin ( {ω}_{v} t + {ϕ}_{1} )$$

where, F₁(t) and G₁(t) denote the fundamental signal of the spacing of the first line set on the scanning line and the fundamental signal of the spacing of second line set on the scanning line, respectively.

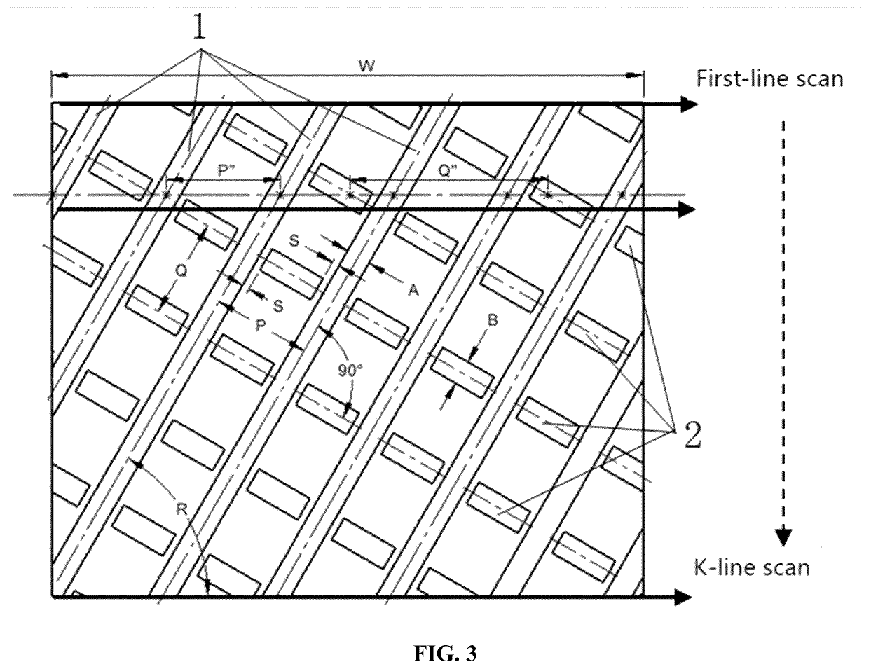

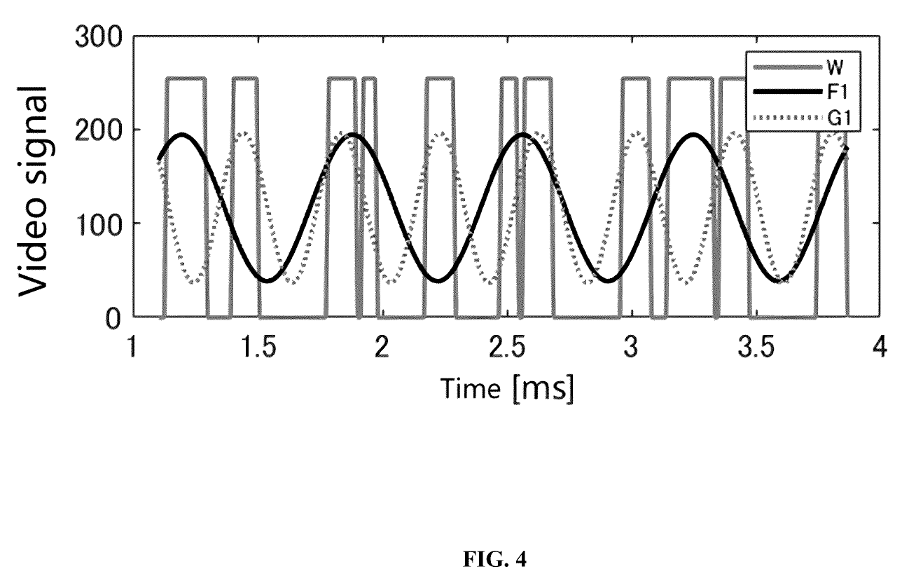

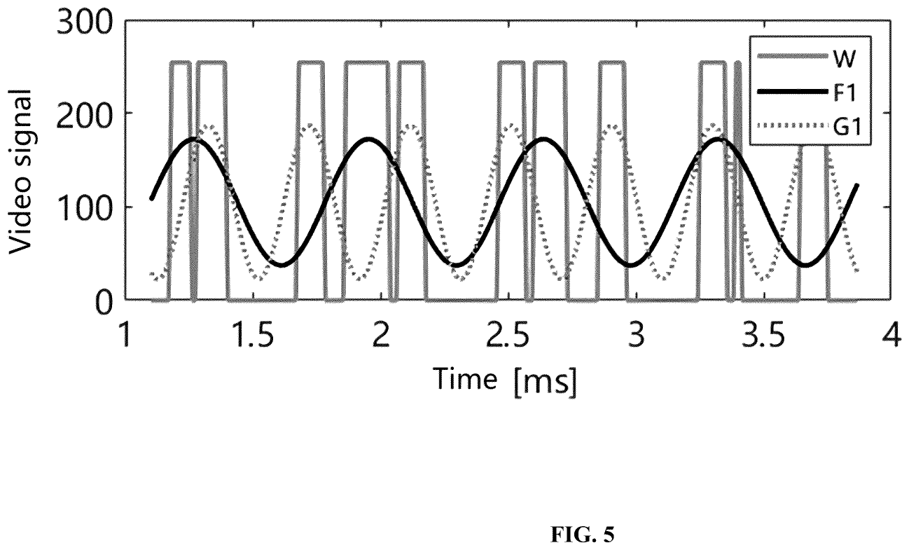

The response of the video signal and each fundamental wave to the electron probe without vibration is shown in FIG. 4; when the electron probe vibrates, the waveform of the video signal and the response of each fundamental wave are shown in FIG. 5. Since the vibration period of the electron probe is usually larger than the line scan period, it can be considered that the probe displacement is constant in each line scan.

When calculating the displacement of the electron probe, the video signal W′(t) is obtained, and the fundamental waves F₁′^{(t)} and G₁′^{(t)} are obtained by Fourier decomposition, which is expressed as follows:

$${W}^{′ ( t )} = {F}_{1}^{′ ( t )} + {G}_{1}^{′ ( t )}$$

$${F}_{1}^{′} ( t ) = {α}_{1}^{′} sin ( {ω}_{u} t + {γ}_{1}^{′} ) , {G}_{1}^{′} ( t ) = {β}_{1}^{′} sin ( {ω}_{v} t + {ϕ}_{1}^{′} )$$

$$where , {α}_{1}^{′} = \sqrt{{( {A}_{1}^{′} )}^{2} + {( {B}_{1}^{′} )}^{2}} , {β}_{1}^{′} = \sqrt{{( {C}_{1}^{′} )}^{2} + {( {D}_{1}^{′} )}^{2}} , {γ}_{1}^{′} = {tan}^{- 1} ( {A}_{1}^{′} / {B}_{1}^{′} ) , {ϕ}_{1}^{′} = {tan}^{- 1} ( {C}_{1}^{′} / {D}_{1}^{′} ) ; {A}_{1}^{′} = \frac{2}{{T}_{s}} {\int }_{0}^{{T}_{s}} {W}^{′} ( t ) cos {ω}_{u} tdt , {B}_{1}^{′} = \frac{2}{{T}_{s}} {\int }_{0}^{{T}_{s}} {W}^{′} ( t ) sin {ω}_{u} tdt , {C}_{1}^{′} = \frac{2}{{T}_{s}} {\int }_{0}^{{T}_{s}} {W}^{′} ( t ) cos {ω}_{v} tdt , {D}_{1}^{′} = \frac{2}{{T}_{s}} {\int }_{0}^{{T}_{s}} {W}^{′} ( t ) sin {ω}_{v} tdt ;$$

F₁′(t) denotes the fundamental signal of the spacing of the first line set on the scanning line obtained in real-time, and G₁′^{(t)} denotes the fundamental signal of the spacing of the second line on the scanning line obtained in real-time; Tₛ denotes the period of each scan, t denotes the time.

In this case, since the vibration period of the electron probe is usually large enough compared to the line scan period, it can be considered that the displacement of the probe is constant at each line scan. Thus, the displacement (uₖ, vₖ) of the electron probe during the kth line scan can be expressed as the change from a stationary value in the phase γ₁′ and ϕ₁′ of the fundamental wave as follows:

$${u}_{k} = P ( {γ}_{1}^{′} - {γ}_{1} ) / ( 2 π ) , {v}_{k} = Q ( {ϕ}_{1}^{′} - {ϕ}_{1} ) / ( 2 π )$$

where γ₁ and ϕ₁ denote a phase of the fundamental signal of the spacing of the first line set on the scanning line and a phase of the fundamental signal of the spacing of the second line set on the scanning line when the electron probe is not vibrating respectively, P denotes the spacing of the first line set, and Q denotes the spacing of the second line set.

Based on the new marker structure pattern, the displacement of the electron probe in two directions can be calculated rapidly by Fourier decomposition according to the video signal scanned by the marker structure pattern, the calculation speed is fast, and real-time control can be realized.

### Embodiment 3

Based on the electron probe positioning pattern provided by the above-mentioned embodiment 1, the embodiment provides an electronic probe displacement measurement method, comprising:
S1: the fundamental amplitude of θ_{N}=[A₁′(t_{N}) B₁′(t_{N}) C₁′(t_{N}) D₁′(t_{N})]^{T} is obtained at the previous time t_{N} of the current time; where the fundamental amplitude θ_{N}[A₁′(t_{N}) B₁′(t_{N}) C₁′(t_{N}) D₁′(t_{N})]^{T} is obtained based on the t={t₁ t₂ . . . t_{N}} electron probe scanning the video signal time-series {W₁′W₂′ . . . W_{N}′} of the electron probe positioning pattern as described in embodiment 1, and W_{N}′ denotes the video signal value at time t_{N};
S2: the video signal value is obtained at the current time t_{N+1}, and the fundamental amplitude θ_{N+1}=[A₁′(t_{N+1}) B₁′(t_{N+1}) C₁′(t_{N+1}) D₁′(t_{N+1})]^{T} at the current time t_{N+1} is determined by the least square method;
S3: the displacement (u(t_{N+1}), V(t_{N+1})) of the probe at the current time t_{N+1} can be expressed as follows:

$$u ( {t}_{N + 1} ) = P ( {γ}_{1}^{′} ( {t}_{N + 1} ) - {γ}_{1} ) / ( 2 π ) , v ( {t}_{N + 1} ) = Q ( {ϕ}_{1}^{′} ( {t}_{N + 1} ) - {ϕ}_{1} ) / ( 2 π )$$

where, γ₁′(t_{N+1})=tan⁻¹[A₁′(t_{N+1})/B₁′(t_{N+1})], ϕ₁′(t_{N+1})=tan⁻¹[C₁′(t_{N+1})/D₁′ (t_{N+1})], γ₁ and ϕ₁ denote the phase of the fundamental signal of the spacing of the first line set on the scanning line and the phase of the fundamental signal of the spacing of the second line set on the scanning line when the electron probe is not vibrating respectively, P denotes the spacing of the first line set, and Q denotes the spacing of the second line set.

As described in embodiment 2, the probe displacement calculation using the Fourier decomposition method is calculated by measuring the video signal during a period of time (e.g., the time taken to perform a line scan). This embodiment shows how to use the recursive least squares method to calculate the probe displacement in real time.

The time-series {W₁′ W₂′ . . . W_{N}′} of the video signal corresponding to the previous time t_{N} to the current time is expressed as follows:

$$[ \begin{matrix}{W}_{1}^{′} \\ {W}_{2}^{′} \\ ⋮ \\ {W}_{N}^{′}\end{matrix} ] = [ \begin{matrix}cos {ω}_{u} {t}_{1} & sin {ω}_{u} {t}_{1} & cos {ω}_{v} {t}_{1} & sin {ω}_{v} {t}_{1} \\ cos {ω}_{u} {t}_{2} & sin {ω}_{u} {t}_{2} & cos {ω}_{v} {t}_{2} & sin {ω}_{v} {t}_{2} \\ ⋮ & ⋮ & ⋮ & ⋮ \\ cos {ω}_{u} {t}_{N} & sin {ω}_{u} {t}_{N} & cos {ω}_{v} {t}_{N} & sin {ω}_{v} {t}_{N}\end{matrix} ] [ \begin{matrix}{A}_{1}^{′} \\ {B}_{1}^{′} \\ {C}_{1}^{′} \\ {D}_{1}^{′}\end{matrix} ] + [ \begin{matrix}{η}_{1} \\ {η}_{2} \\ ⋮ \\ {η}_{N}\end{matrix} ]$$

where η_{N} denotes the error at time t_{N}; ωᵤ=2π/Tᵤ, ωᵥ=2π/Tᵥ, Tᵤ=P″/V, Tᵤ=Q″/V, V denotes the scanning speed of the electron probe, P″ and Q″ denote the spacing of the first line set on the scanning line and the spacing of the second line on the scanning line, respectively; the fundamental amplitude θ_{N}=[A₁′(t_{N}) B₁′(t_{N}) C₁′(t_{N}) D₁′(t_{N})]^{T} is expressed as follows:

$${θ}_{N} = {P}_{N} {\sum }_{j = 1}^{N} {z}_{j} {W}_{j}^{′}$$

where, zⱼ^{T}=[cos ωᵤtⱼ sin ωᵤtⱼ cos ωᵥtⱼ sin ωᵥtⱼ], P_{N}=(Σⱼ₌₁^{N}zⱼzⱼ^{T})⁻¹);
the fundamental amplitude θ_{N+1} and P_{N+1} at the next time can be calculated consecutively by using the least squares method. The fundamental amplitude θ_{N+1} and P_{N+1} corresponding to the time-series {W₁′ W₂′ . . . W_{N+1}′} of the video signal corresponding to the current time t_{N+1} can be determined by the least square method as follows:

$$\begin{matrix}{θ}_{N + 1} = {[ \begin{matrix}{A}_{1}^{′} ( {t}_{N + 1} ) & {B}_{1}^{′} ( {t}_{N + 1} ) & {C}_{1}^{′} ( {t}_{N + 1} ) & {D}_{1}^{′} ( {t}_{N + 1} )\end{matrix} ]}^{T} \\ = {θ}_{N} + \frac{{P}_{N} {z}_{N + 1}}{1 + {z}_{N + 1}^{T} {P}_{N} {z}_{N + 1}} ( {W}_{N + 1}^{′} - {z}_{N + 1}^{T} {θ}_{N} )\end{matrix} \\ {P}_{N + 1} = {P}_{N} - \frac{{P}_{N} {z}_{N + 1} {z}_{N + 1}^{T} {P}_{N}}{1 + {z}_{N + 1}^{T} {P}_{N} {z}_{N + 1}}$$

where W_{N+1}′ denotes the video signal value at the current time t_{N+1}.

Therefore, the probe displacement (u(tⱼ),v(tⱼ)) at any time tⱼ can be calculated according to θⱼ^{T}=[A₁′(tⱼ) B₁′(tⱼ) C₁′(tⱼ) D₁′(tⱼ)]

$$u ( {t}_{j} ) = P ( {γ}_{1}^{′} ( {t}_{j} ) - {γ}_{1} ) / ( 2 π ) , v ( {t}_{j} ) = Q ( {ϕ}_{1}^{′} ( {t}_{j} ) - {ϕ}_{1} ) / ( 2 π )$$

where, γ₁′(tⱼ)=tan⁻¹[A₁′(tⱼ)/B₁′(tⱼ)], ϕ₁′(tⱼ)=tan⁻¹[C′(tⱼ)/D₁′(tⱼ)], γ₁ and ϕ₁ denote the phase of the fundamental signal of the spacing of the first line set on the scanning line and the phase of the fundamental signal of the spacing of the second line set on the scanning line when the electron probe is not vibrating respectively, P denotes the spacing of the first line set, and Q denotes the spacing of the second line set.

Based on the new marker structure pattern, the displacement of electron probe in two directions can be calculated rapidly by recursive least squares algorithm according to the video signal scanned by the marker structure pattern, the calculation speed is fast and real-time control can be realized.

### Embodiment 4

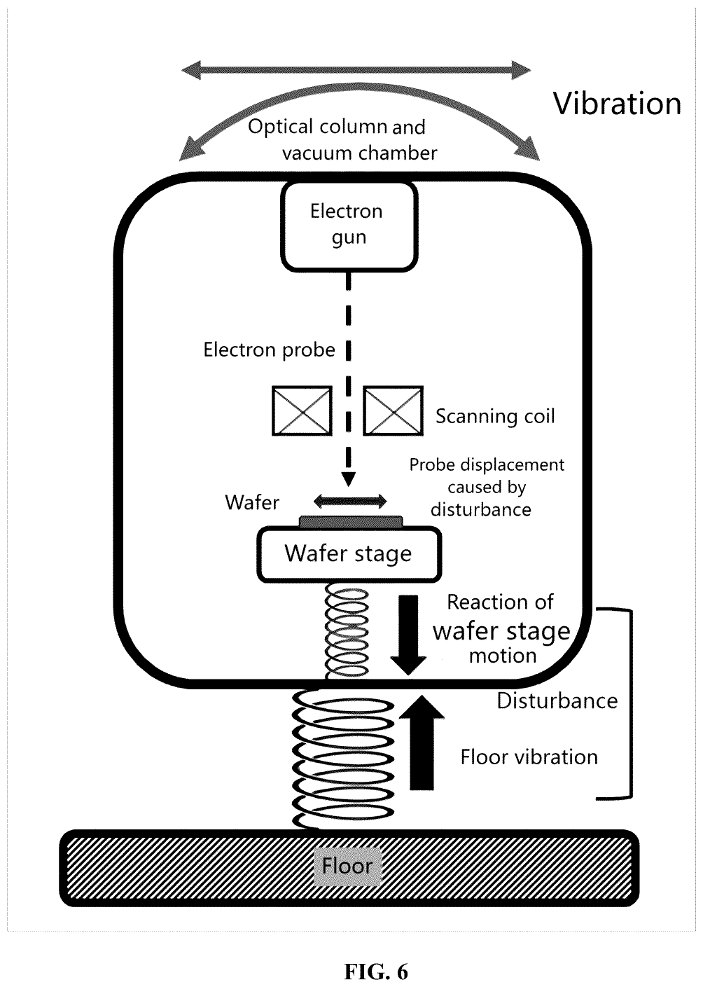

Based on the above-mentioned embodiment 2 or embodiment 3, the embodiment provides an electronic probe positioning control method, comprising:
the measurement values of multiple accelerometers arranged on a vacuum chamber, an optical column, and a wafer stage are obtained in real-time, and input them into a feed-forward controller to obtain a first input voltage of a scanning coil;
a real-time displacement of an electronic probe is obtained by using the electronic probe displacement measurement method as described in embodiment 2 or embodiment 3, and input them into a feed-forward controller to obtain a second input voltage of a scanning coil;
the scanning coil voltage is controlled in real-time according to a final input voltage obtained by integrating the first input voltage and the second input voltage of the scanning coil. Wherein the integrating process is adding the first input voltage and the second input voltage.

Wherein, the design method of the feed-forward controller is expressed as follows:
a mechanical dynamics analysis diagram of the electron beam lithography equipment is shown in FIG. 6, the vibration of the lithography equipment comes from the vibration of the floor or the vibration of the lower part of the wafer stage caused by the reaction force of the accelerated motion of the wafer stage. By installing J accelerometers on the vacuum chamber, the optical column, and the wafer stage, the relationship between the displacement of the electron probe (u, v) and the output of the accelerometer δ₁, δ₂, . . . δ_{J} in the frequency domain is expressed as follows:

$$[ \begin{matrix}u \\ v\end{matrix} ] = G [ \begin{matrix}{δ}_{1} \\ {δ}_{2} \\ ⋮ \\ {δ}_{J}\end{matrix} ]$$

where, G denotes the transfer function from the measured values of multiple accelerometers to the displacement of the electron probe, which is measured by vibration test. The vibration test is to use a shaker to perform overall vibration on the device or to perform local vibration on the device through the wafer stage, as mentioned earlier, the probe displacement is measured using a new substrate's marker structure pattern; moreover, the calibration of the scanning coil is also carried out in the same way as the vibration test. Firstly, the relationship between the input voltage of the scanning coil (Vₓ, V_{y}) and the displacement of the electron probe (u, v) is as follows:

$$[ \begin{matrix}u \\ v\end{matrix} ] = C [ \begin{matrix}{V}_{x} \\ {V}_{y}\end{matrix} ]$$

where, C denotes the transfer matrix of the electron probe displacement to the first input voltage of the scanning coil, when a random signal or a sinusoidal signal is input into the scanning coil, the electron probe displacement can be determined by the marker structure pattern of the new substrate to determine the matrix transfer C. Moreover, unlike the transfer function G, the transfer matrix C is independent of frequency. As mentioned above, if the input voltage (Vₓ, V_{y}) in both directions of the scanning coil is selected as follows, the electron probe displacement (u, v) caused by floor vibration and wafer stage movement can be eliminated.

$$[ \begin{matrix}{V}_{x} \\ {V}_{y}\end{matrix} ] = {C}^{- 1} G [ \begin{matrix}{δ}_{1} \\ {δ}_{2} \\ ⋮ \\ {δ}_{J}\end{matrix} ]$$

the above expression is the final feed-forward controller expression.

The design method of the feedback controller is as follows:
the feedback controller uses the classical feedback control algorithm to suppress the displacement of the probe, so the feedback controller is expressed as follows:

$$[ \begin{matrix}{V}_{x} ( {t}_{j} ) \\ {V}_{y} ( {t}_{j} )\end{matrix} ] = {C}^{- 1} \{ [ \begin{matrix}{k}_{pu} & 0 \\ 0 & {k}_{pv}\end{matrix} ] [ \begin{matrix}u ( {t}_{j} ) \\ v ( {t}_{j} )\end{matrix} ] + [ \begin{matrix}{k}_{du} & 0 \\ 0 & {d}_{dv}\end{matrix} ] [ \begin{matrix}\dot{u} ( {t}_{j} ) \\ \dot{v} ( {t}_{j} )\end{matrix} ] \}$$

where, (Vₓ(tⱼ), V_{y}(tⱼ)) denotes the second input voltage of the scanning coil at time tⱼ, (u(tⱼ), v(tⱼ)) denotes the probe displacement at time tⱼ, kₚᵤ, kₚᵥ, k_{du}, k_{dv} are gain coefficients; the “\dot{ }” in \dot{u}(tⱼ) and \dot{v}(tⱼ) denotes a derivative.

### Embodiment 5

the embodiment provides an electron beam lithography equipment, and the substrate adopts an electron probe positioning pattern as described in embodiment 1, which comprises a marker region 3 and an exposure region 4;
the light beam device adopts a multi-beam device, in which one electron probe is used to scan the marker region, and other probes are used to scan the exposure region.

The electron beam lithography equipment provided in this embodiment has multiple accelerometers mounted on the vacuum chamber, optical column, and wafer stage, multiple accelerometers are connected to the control system, and the control system also obtains the video signal obtained by scanning the marker region on the substrate by electron probe, the control system is also configured to perform the electron probe positioning control method as described in embodiment 4, the control system generates the input voltage of the scanning coil based on the measured value of the accelerometer and the video signal to control the scanning coil.

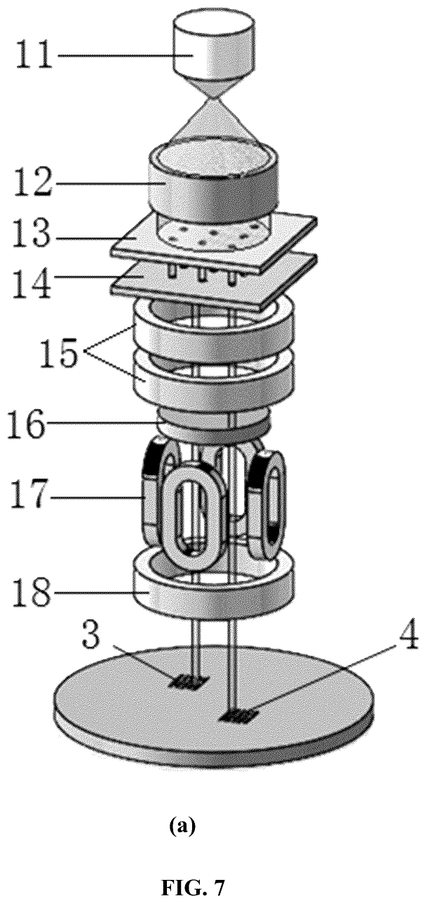

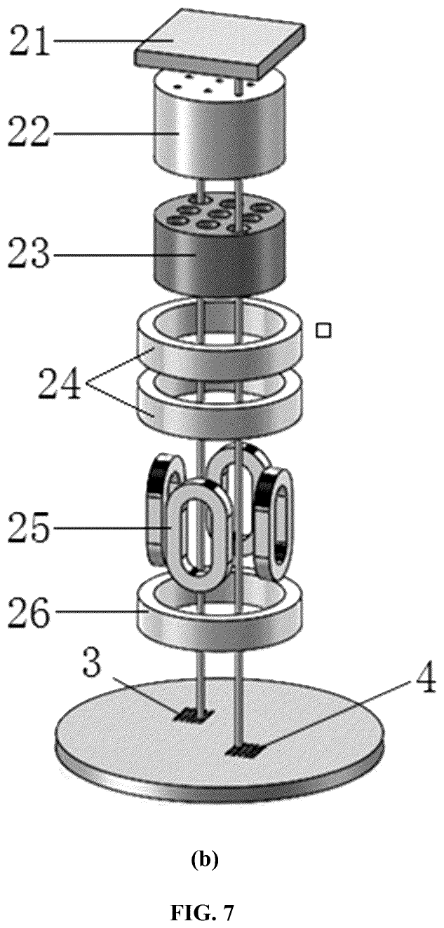

The substrate consists of two regions, marker region 3 and exposure region 4 (photoresist layer for exposure), the marker region and the exposure region can be illuminated by the beam at the same time by using a multi-beam device. In this embodiment, two types of multi-beam devices are provided, as shown in FIG. 7a, which are single electron source multi-beam devices, comprising an electron gun 11, a collimator 12, an aperture array 13, a beam blanker array 14, a condenser lens 15, an aperture 16, a scanning coil 17, an objective lens 18, the electron beam is switched at high speed in two regions by beam blanker array 14, the function of beam blanker array 14 itself is to deflect the beam by electrostatic lens or similar device and block the beam at the non-opening of the aperture; as shown in FIG. 7b, which is a multi-beam device with multiple electron sources, comprising a light controller 21, a multi-optical power supply 22, a condenser lens array 23, a condenser lens 24, a scanning coil 25, an objective lens 26, which does not require beam blanker array, and multiple electron probes to scan the marker region and exposure region at the same time. The video signal of the marker region scanning is used as a benchmark for real-time calculation and control of probe displacement.

It should be noted that other specific structures of the electron beam lithography apparatus are not an improvement of the present invention and will not be described further herein.

Other embodiments of the present invention also provide a computer-readable storage medium on which a computer program is stored, and the computer program is used to implement a method as described in embodiment 2 or embodiment 3, or embodiment 4.

It is understandable that the same or similar parts of each of the above-mentioned embodiments can refer to each other, and the contents that are not detailed in some embodiments can refer to the same or similar contents in other embodiments.

Technical personnel in this field should understand that the embodiment of this application can be provided as a method, system, or computer program product. Therefore, this application may take the form of a full hardware embodiment, a full software embodiment, or a combination of software and hardware embodiments. Moreover, this application can be implemented in the form of computer program products on one or more computer-available storage media (comprising but not limited to disk storage, CD-ROM, optical storage, etc.) containing computer-available program code.

The present application is described with reference to flowchart illustrations and/or block diagrams of methods, apparatus (systems), and computer program products according to embodiments of the present application. It will be understood that each flow and/or block of the flowcharts and/or block diagrams, and combinations of flows and/or blocks in the flowcharts and/or block diagrams, can be implemented by computer program instructions. These computer program instructions may be provided to a processor of a general-purpose computer, special-purpose computer, embedded processor, or other programmable data processing apparatus to produce a machine, such that the instructions, which execute via the processor of the computer or other programmable data processing apparatus, create means for implementing the functions specified in a flowchart of a process or multiple processes and/or a block diagram of a block or multiple blocks.

These computer program instructions can also be stored in a computer-readable memory that can guide a computer or other programmable data processing device to work in a specific way, so that the instructions stored in the computer-readable memory generate a manufacturing product that comprises an instruction device that implements the functions specified in a flowchart of a process or multiple processes and/or a block diagram of a block or multiple blocks.

These computer program instructions can also be loaded onto a computer or other programmable data processing device, so that a series of operation steps are performed on the computer or other programmable device to generate computer-implemented processing, so that the instructions executed on the computer or other programmable device provide the steps for implementing the functions specified in a flowchart of a process or multiple processes and/or a block diagram of a block or multiple blocks.

While embodiments of the present invention have been shown and described, it will be understood that the above-described embodiments are illustrative and not restrictive, and that changes, modifications, substitutions and alterations may be made by those skilled in the art without departing from the scope of the present invention.

What is claimed is:

1. An electron probe positioning pattern, a marker region of the electron probe positioning pattern comprises a first line set composed of multiple continuous first lines and a second line set composed of multiple discontinuous second lines, the first line set and the second line set are orthogonal, and a spacing of the first line set on a scanning line is not equal to a spacing of the second line set on the scanning line.

2. The electron probe positioning pattern according to claim 1, the spacing of the first line set on the scanning line and the spacing of the second line set on the scanning line satisfy the following conditions:
$${P}^{″} = P / sin R , {Q}^{″} = Q / cos R \\ {P}^{″} = α {Q}^{″} \\ α > 3 / 2 or α < 2 / 3$$
where P denotes the spacing of the first line set on the scanning line; Q denotes the spacing of the second line set on the scanning line; P denotes the spacing of the first line set, Q denotes the spacing of the second line set; R denotes an angle between the scanning line and the first line set.

3. The electron probe positioning pattern according to claim 1, the projection lengths of the following three on the scanning line are greater than the horizontal pixel resolution; a line width of the first line, a line width of the second line, and a spacing between the adjacent first and second lines.

4. An electronic probe displacement measurement method, comprising:
obtaining an electron probe scanning video signal W′(t) of the electron probe positioning pattern in real-time according to claim 1;
the Fourier decomposition of the video signal W′(t) is performed to obtain its fundamental waves F₁′^{(t)} and G₁′^{(t)}, as well as the phases γ₁′ and ϕ₁′ of F₁′^{(t)} and G₁′^{(t)}; F₁′^{(t)} and G₁′^{(t)} denote a fundamental signal of the spacing of the first line set on the scanning line and the fundamental signal of the spacing of second line set on the scanning line obtained in real-time, respectively;
a displacement (u,v) of the current scanning round of the electron probe is expressed as follows:
$$u = P ( {γ}_{1}^{′} - {γ}_{1} ) / ( 2 π ) , v = Q ( {ϕ}_{1}^{′} - {ϕ}_{1} ) / ( 2 π )$$
where γ₁ and ϕ₁ denote a phase of the fundamental signal of the spacing of the first line set on the scanning line and a phase of the fundamental signal of the spacing of the second line set on the scanning line when the electron probe is not vibrating respectively, P denotes the spacing of the first line set, and Q denotes the spacing of the second line set.

5. The electronic probe displacement measurement method according to claim 4, the video signal W′(t) is decomposed into its fundamental waves F₁′^{(t)} and G₁′^{(t)}, which are denoted as follows:
$${W}^{′ ( t )} = {F}_{1}^{′ ( t )} + {G}_{1}^{′ ( t )} \\ {F}_{1}^{′} ( t ) = {α}_{1}^{′} sin ( {ω}_{u} t + {γ}_{1}^{′} ) , {G}_{1}^{′} ( t ) = {β}_{1}^{′} sin ( {ω}_{v} t + {ϕ}_{1}^{′} ) \\ where , {α}_{1}^{′} = \sqrt{{( {A}_{1}^{′} )}^{2} + {( {B}_{1}^{′} )}^{2}} , {β}_{1}^{′} = \sqrt{{( {C}_{1}^{′} )}^{2} + {( {D}_{1}^{′} )}^{2}} , \\ {γ}_{1}^{′} = {tan}^{- 1} ( {A}_{1}^{′} / {B}_{1}^{′} ) , {ϕ}_{1}^{′} = {tan}^{- 1} ( {C}_{1}^{′} / {D}_{1}^{′} ) ; \\ {A}_{1}^{′} = \frac{2}{{T}_{s}} {\int }_{0}^{{T}_{s}} {W}^{′} ( t ) cos {ω}_{u} tdt , {B}_{1}^{′} = \frac{2}{{T}_{s}} {\int }_{0}^{{T}_{s}} {W}^{′} ( t ) sin {ω}_{u} tdt , \\ {C}_{1}^{′} = \frac{2}{{T}_{s}} {\int }_{0}^{{T}_{s}} {W}^{′} ( t ) cos {ω}_{v} tdt , {D}_{1}^{′} = \frac{2}{{T}_{s}} {\int }_{0}^{{T}_{s}} {W}^{′} ( t ) sin {ω}_{v} tdt ;$$
F₁′(t) denotes the fundamental signal of the spacing of the first line set on the scanning line obtained in real-time, and G₁′^{(t)} denotes the fundamental signal of the spacing of the second line set on the scanning line obtained in real-time; Tₛ denotes a period of each scan, t denotes a time; ωᵤ=2π/Tᵤ, ωᵥ=2π/Tᵥ, Tᵤ=P″/V, T=Q″/V, V denotes a scanning speed of the electron probe, P″ and Q″ denote the spacing of the first line set on the scanning line and the spacing of the second line set on the scanning line, respectively.

6. The electronic probe displacement measurement method, comprising:
obtaining a fundamental amplitude of θ_{N}=[A₁′(t_{N}) B₁′(t_{N}) C₁′(t_{N}) D₁′(t_{N})]^{T} at the previous time t_{N} of the current time; where the fundamental amplitude θ_{N}=[A₁′(t_{N}) B₁′(t_{N}) C₁′(t_{N}) D₁′(t_{N})]^{T} is obtained based on the t={t₁ t₂ . . . t_{N}} electron probe scanning a video signal time-series {W₁′ W₂′ . . . W_{N}′} of the electron probe positioning pattern as described in the first aspect, and W_{N}′ denotes a video signal value at time t_{N};
obtaining the video signal value of t_{N+1} at the current time, and the fundamental amplitude θ_{N+1}=[A₁′(t_{N+1}) B₁′(t_{N+1}) C₁′(t_{N+1}) D₁′(t_{N+1})]^{T} at the current time t_{N+1} is determined by a least square method;
a displacement (u(t_{N+1}), V(t_{N+1})) of the probe at a current time t_{N+1} can be expressed as follows:
$$u ( {t}_{N + 1} ) = P ( {γ}_{1}^{′} ( {t}_{N + 1} ) - {γ}_{1} ) / ( 2 π ) , v ( {t}_{N + 1} ) = Q ( {ϕ}_{1}^{′} ( {t}_{N + 1} ) - {ϕ}_{1} ) / ( 2 π ) \\ where , \\ {γ}_{1}^{′} ( {t}_{N + 1} ) = {tan}^{- 1} [ {A}_{1}^{′} ( {t}_{N + 1} ) / {B}_{1}^{′} ( {t}_{N + 1} ) ] , {ϕ}_{1}^{′} ( {t}_{N + 1} ) = {tan}^{- 1} [ {C}_{1}^{′} ( {t}_{N + 1} ) / {D}_{1}^{′} ( {t}_{N + 1} ) ] ,$$
γ₁ and ϕ₁ denote the phase of the fundamental signal of the spacing of the first line set on the scanning line and the phase of the fundamental signal of the spacing of the second line set on the scanning line when the electron probe is not vibrating respectively, P denotes the spacing of the first line set, and Q denotes the spacing of the second line set.

7. The electronic probe displacement measurement method according to claim 6, the video signal time-series {W₁′ W₂′ . . . W_{N}′} is expressed as follows:
$$[ \begin{matrix}{W}_{1}^{′} \\ {W}_{2}^{′} \\ ⋮ \\ {W}_{N}^{′}\end{matrix} ] = [ \begin{matrix}cos {ω}_{u} {t}_{1} & sin {ω}_{u} {t}_{1} & cos {ω}_{v} {t}_{1} & sin {ω}_{v} {t}_{1} \\ cos {ω}_{u} {t}_{2} & sin {ω}_{u} {t}_{2} & cos {ω}_{v} {t}_{2} & sin {ω}_{v} {t}_{2} \\ ⋮ & ⋮ & ⋮ & ⋮ \\ cos {ω}_{u} {t}_{N} & sin {ω}_{u} {t}_{N} & cos {ω}_{v} {t}_{N} & sin {ω}_{v} {t}_{N}\end{matrix} ] [ \begin{matrix}{A}_{1}^{′} \\ {B}_{1}^{′} \\ {C}_{1}^{′} \\ {D}_{1}^{′}\end{matrix} ] + [ \begin{matrix}{η}_{1} \\ {η}_{2} \\ ⋮ \\ {η}_{N}\end{matrix} ]$$
where, η_{N} denotes the error at time t_{N}; ωᵤ=2π/Tᵤ, ωᵥ=2π/Tᵥ, Tᵤ=P″/V, Tᵥ=Q″/V, V denotes the scanning speed of the electron probe, P″ and Q″ denote the spacing of the first line set on the scanning line and the spacing of the second line on the scanning line, respectively; the fundamental amplitude θ_{N}=[A₁′(t_{N}) B₁′(t_{N}) C₁′(t_{N}) D₁′(t_{N})]^{T} is expressed as follows:
$${θ}_{N} = {P}_{N} {\sum }_{j = 1}^{N} {z}_{j} {W}_{j}^{′}$$
where, zⱼ^{T}=[cos ωᵤtⱼ sin ωⱼtⱼ cos ωᵥtⱼ sin ωᵥtⱼ], P_{N}=(Σⱼ₌₁^{N}zⱼzⱼ^{T})⁻¹;
the least square method is used to determine the amplitude θ_{N+1} and θ_{N+1} of the fundamental wave at the current time t_{N+1} is expressed as follows:
$$\begin{matrix}{θ}_{N + 1} = {[ \begin{matrix}{A}_{1}^{′} ( {t}_{N + 1} ) & {B}_{1}^{′} ( {t}_{N + 1} ) & {C}_{1}^{′} ( {t}_{N + 1} ) & {D}_{1}^{′} ( {t}_{N + 1} )\end{matrix} ]}^{T} \\ = {θ}_{N} + \frac{{P}_{N} {z}_{N + 1}}{1 + {z}_{N + 1}^{T} {P}_{N} {z}_{N + 1}} ( {W}_{N + 1}^{′} - {z}_{N + 1}^{T} {θ}_{N} )\end{matrix} \\ {P}_{N + 1} = {P}_{N} - \frac{{P}_{N} {z}_{N + 1} {z}_{N + 1}^{T} {P}_{N}}{1 + {z}_{N + 1}^{T} {P}_{N} {z}_{N + 1}}$$
where W_{N+1}′ denotes a video signal value at the current time t_{N+1}.

8. An electronic probe positioning control method, comprising:
obtaining measurement values of multiple accelerometers arranged on a vacuum chamber, an optical column and a wafer stage in real-time, and inputting them into a feed-forward controller to obtain a first input voltage of a scanning coil;
obtaining a real-time displacement of an electronic probe using the electronic probe displacement measurement method according to claim 4, and inputting them into a feedback controller to obtain a second input voltage of a scanning coil;
controlling the scanning coil voltage in real-time according to a final input voltage obtained by integrating the first input voltage and a second input voltage of the scanning coil.

9. The electronic probe positioning control method according to claim 8, the feed-forward controller is expressed as follows:
$$[ \begin{matrix}{V}_{x} \\ {V}_{y}\end{matrix} ] = {C}^{- 1} G [ \begin{matrix}{δ}_{1} \\ {δ}_{2} \\ ⋮ \\ {δ}_{J}\end{matrix} ]$$
where, (Vₓ, V_{y}) denotes a first input voltage of the scanning coil, δ_{J} denotes a measured value of the Jth accelerometer, G denotes a transfer function from the measured values of multiple accelerometers to the displacement of the electron probe, and C denotes a transfer matrix from the displacement of the electron probe to the first input voltage of the scanning coil;
the feedback controller is expressed as follows:
$$[ \begin{matrix}{V}_{x} ( {t}_{j} ) \\ {V}_{y} ( {t}_{j} )\end{matrix} ] = {C}^{- 1} \{ [ \begin{matrix}{k}_{pu} & 0 \\ 0 & {k}_{pv}\end{matrix} ] [ \begin{matrix}u ( {t}_{j} ) \\ v ( {t}_{j} )\end{matrix} ] + [ \begin{matrix}{k}_{du} & 0 \\ 0 & {k}_{dv}\end{matrix} ] [ \begin{matrix}\dot{u} ( {t}_{j} ) \\ \dot{v} ( {t}_{j} )\end{matrix} ] \}$$
where, (Vₓ(tⱼ), V_{y}(tⱼ)) denotes the second input voltage of the scanning coil at time tⱼ, (u(tⱼ), v(tⱼ)) denotes a probe displacement at time tⱼ, kₚᵤ, kₚᵥ, k_{du}, k_{dv} are gain coefficients.

10. An electron beam lithography equipment, the substrate adopts an electron probe positioning pattern according to claim 1, which comprises a marker region and an exposure region;
a light beam device adopts a multi-beam device, in which one electron probe is used to scan the marker region and the other electron probes are used to scan the exposure region.

11. An electronic probe positioning control method, comprising:
obtaining measurement values of multiple accelerometers arranged on a vacuum chamber, an optical column and a wafer stage in real-time, and inputting them into a feed-forward controller to obtain a first input voltage of a scanning coil;
obtaining a real-time displacement of an electronic probe using the electronic probe displacement measurement method according to claim 6, and inputting them into a feedback controller to obtain a second input voltage of a scanning coil;
controlling the scanning coil voltage in real-time according to a final input voltage obtained by integrating the first input voltage and a second input voltage of the scanning coil.
